(19) United States
(12) Patent Application Publication
(10) Pub. No.: US 2016/0072500 A1
(43) Pub. Date: Mar. 10, 2016

(54) CONTROLLER, CONVERTER AND CONTROL METHOD

(71) Applicant: Kabushiki Kaisha Toshiba, Tokyo (JP)

(72) Inventor: Toshiyuki Naka, Nonoichi Ishikawa (JP)

(21) Appl. No.: 14/643,520

(22) Filed: Mar. 10, 2015

(30) Foreign Application Priority Data
Sep. 4, 2014 (JP) 2014-179959

(51) Int. Cl. H03K 17/687; H02M 1/00; H02M 3/158

(52) U.S. Cl. CPC H03K 17/687; H02M 3/158; H02M 1/00; H02M 2001/0003

(57) ABSTRACT

According to one embodiment, a controller includes a processor. The controller is able to control a switching element. The processor changes a gate voltage applied to a gate terminal of the switching element from a first voltage value to a second voltage value, and controls the gate voltage to the first voltage value when a drain current flowing through a drain terminal of the switching element increases.

### CROSS-REFERENCE TO RELATED APPLICATIONS

This application is based upon and claims the benefit of priority from Japanese Patent Application No. 2014-179959, filed on Sep. 4, 2014; the entire contents of which are incorporated herein by reference.

### FIELD

Embodiments described herein relate generally to a controller, a converter and a control method.

### BACKGROUND

A switching power source converts an input direct voltage to a desired direct voltage by using a DC (Direct Current)-DC converter. In the DC-DC converter, for example, a transistor based on a nitride semiconductor is adopted as a switching element. According to this, an on-resistance is small, switching operation is possible at a high speed, and power consumption is reduced. In the switching element, more high efficiency is desired.

### BRIEF DESCRIPTION OF THE DRAWINGS

FIG. 1 is a circuit diagram illustrating a controller of a first embodiment;

FIG. 2 is a flow chart illustrating a control method of the controller of the first embodiment;

FIG. 3 is a graph illustrating an on-resistance characteristic of a normally-on switching element;

FIG. 4 is a circuit diagram illustrating a converter of a second embodiment;

FIG. 5 is a circuit diagram illustrating a converter of a third embodiment;

FIG. 6 is a block diagram illustrating the controller of the embodiment;

FIG. 7 is a circuit diagram illustrating a converter of a fourth embodiment;

FIG. 8 is a circuit diagram illustrating a converter of a fifth embodiment; and

FIG. 9 is a graph illustrating an on-resistance characteristic of a normally-off switching element.

### DETAILED DESCRIPTION

According to one embodiment, a controller includes a processor. The controller is able to control a switching element. The processor changes a gate voltage applied to a gate terminal of the switching element from a first voltage value to a second voltage value, and controls the gate voltage to the first voltage value when a drain current flowing through a drain terminal of the switching element increases.

According to another embodiment, a converter includes a first switching element and a first controller. The first switching element includes a first source terminal, a first gate terminal, and a first drain terminal. The first controller includes a processor which controls the first switching element. The processor changes a gate voltage applied to the first gate terminal from a first voltage value to a second voltage value, and controls the gate voltage to the first voltage value when a drain current flowing through the first drain terminal increases.

According to another embodiment, a control method is disclosed for controlling switching element. The method can include performing a processing for changing a gate voltage applied to a gate terminal of the switching element from a first voltage value to a second voltage value. In addition, the method can include performing a processing for controlling the gate voltage to the first voltage value when a drain current flowing through a drain terminal of the switching element increases.

Various embodiments will be described hereinafter with reference to the accompanying drawings.

The drawings are schematic and conceptual, and the relationships between the thickness and width of portions, the size ratio among portions, etc., are not necessarily the same as the actual values thereof. Further, the dimensions and proportions may be illustrated differently among drawings, even for identical portions.

In the present specification and drawings, the same elements as those described previously with reference to earlier figures are labeled with like reference numerals, and the detailed description thereof is omitted as appropriate.

### First Embodiment

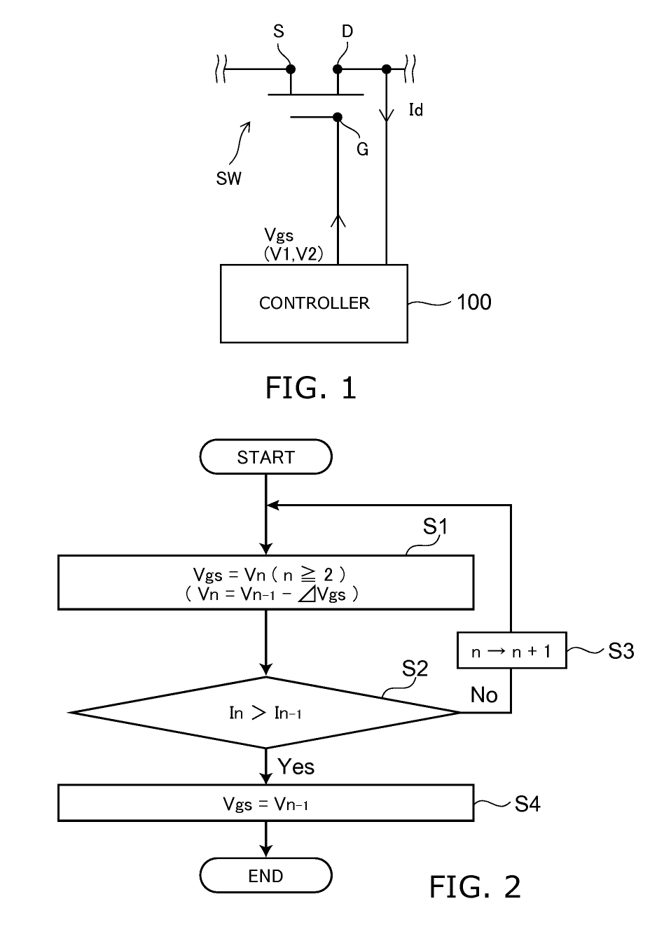

FIG. 1 is a circuit diagram illustrating a controller of a first embodiment.

As shown in FIG. 1, the controller 100 is connectable to a switching element SW, and controls switching operation of the switching element SW. The switching element SW is, for example, incorporated into various converters of a step-down type, a step-up type, and a step-up/down type, and functions as a switch to turn on/off the input voltage in the converter.

The switching element SW is a normally-on element, and includes a source terminal S, a gate terminal G and a drain terminal D. The normally-on element is an element which enters on-state without applying a voltage to the gate terminal, and is also called a depression type. In contrast, the normally-off element is an element which enters off-state without applying a voltage to the gate terminal, and is also called an enhancement type. The switching element SW is, for example, a high electron mobility transistor (HEMT) based on a nitride semiconductor. The nitride semiconductor includes, for example, gallium nitride (GaN). In FIG. 1, HEMT of the JFET (Junction Field-Effect Transistor) type is shown as an example of the switching element SW. The switching element SW may be HEMT of the MOSFET (Metal Oxide Semiconductor Field-Effect Transistor) type. The switching element SW may be one of a normally-on type and a normally-off type.

The controller 100 is a control device including, for example, CPU (Central Processor) and a memory or the like. A portion or entirety of the controller 100 may include an integrated circuit such as LSI (Large Scale Integration) or the like or IC (Integrated Circuit) chip set. The controller 100 may include an individual circuit, and may include a circuit integrating the portion or the entirety. Integration may include a dedicated circuit or a general-purpose processor without limiting to LSI.

The controller 100 includes, for example, a PWM (Pulse Width Modulation) generation circuit not shown, and applies a pulse-like gate voltage (inter gate-source voltage) Vgs to the gate terminal of the switching element SW.

The switching element SW performs on-off operation in response to the gate voltage Vgs applied from the controller 100, and is PWM driven. That is, the normally-on element is turned on in a state (gate voltage Vgs=0) where the gate voltage Vgs is not applied. In the on-state, a current flows between the source and the drain, and a drain current Id flows. On the other hand, the normally-on element is turned off, in a state where a prescribed voltage is applied as the gate voltage Vgs. In the off-state, a current does not flow between the source and the drain, and the drain current Id does not flow.

The switching element SW has a so-called on-resistance because of being a transistor. The on-resistance is a resistance between the source and the drain in the on-state of the transistor. The switching element SW performs the switching operation of turning on/off based on the property that the resistance between the source and the drain varies depending on the gate voltage Vgs applied between the gate and the source.

When the switching element SW is turned on, a current flows between the source and the drain. This current and the on-resistance produce a voltage and a power loss occurs. Specifically, the produced power is converted to heat by the switching element SW to be the loss. The large on-resistance means power loss increase.

The on-resistance can be small and the switching operation speed can be high by adopting HEMT based on GaN as the switching element SW. This allows the power loss to be suppressed. However, HEMT is a normally-on element, and thus turns on without application of the gate voltage. Because of the switching operation, HEMT is turned off by applying a negative voltage as the gate voltage. At this time, the gate voltage is desired to be as low as possible in order to surely turn off HEMT. On the other hand, HEMT has characteristic that too much low gate voltage increases the on-resistance. This characteristic varies with respect to each element, and thus it is favorable to set a suitable voltage with respect to each element.

The controller 100 according to the embodiment performs a first processing for changing the gate voltage Vgs applied to the terminal G of the switching element SW from a first voltage value V1 to a second voltage value V2, a second processing determining whether the drain current Id flowing through the drain terminal D of the switching element SW increases or not, and a third processing controlling the gate voltage Vgs to the first voltage value V1 when the drain current Id is judged to increase.

The first to third processing, for example, can be performed by software control. That is, the first to third processing can be performed by using program. The first to third processing may be performed by hardware control.

In the converter incorporating the switching element SW, feedback control is usually performed. In the feedback control, the output value is controlled to be constantly reference value (constant). When the on-resistance of the switching element SW increases, the power loss increases and the output voltage decreases. In order to return the lowered output voltage to the reference value, the drain current Id is increases. This keeps the output voltage to the reference value.

That is, the increase of the drain current Id means the increase of the on-resistance (increase of power loss). For this reason, detection of the drain current Id increase allows the increase of the on-resistance to be detected. The controller 100 sets the first voltage value V1 as the gate voltage Vgs, performs the switching operation on the basis of the first voltage value V1, and memories the value of the drain current Id. In this example, the first voltage value V1 is an initial value. The second voltage value is set as the gate voltage Vgs. The switching element SW is a normally-on type, and thus both of the first voltage value V1 and the second voltage value V2 are negative voltage values. For example, the absolute value of the second voltage value V2 is larger than the absolute value of the first voltage value V1. That is, the second voltage value V2 is a value lower than the first voltage value V1. The controller 100 performs the switching operation on the basis of the second voltage value V2, and determines whether the drain current Id increases or not. When the drain current ID is judged to increase, the first voltage value V1 used just before the second voltage value V2 is set as the gate voltage Vgs. When the drain current Id is judged not to increase, a negative voltage value further lower than the second voltage value V2 is set as the gate voltage Vgs and the similar processing is repeated.

In this example, the first voltage value V1 is a voltage value of the gate voltage Vgs at the lowest on-resistance. In the embodiment, while changing the voltage value of the gate voltage Vgs, the increase of the drain current Id is detected. Thereby, the voltage value of the gate voltage Vgs at the lowest on-resistance is detected, and the detected voltage value is set as the gate voltage Vgs of the switching element SW.

The set of the gate voltage Vgs may be made regularly at a prescribed timing, alternately may be made irregularly at an arbitrary timing. Thereby, the on-resistance of the switching element SW can be small and the power loss can be suppressed. Thereby, the switching element SW can be controlled efficiently.

FIG. 2 is a flow chart illustrating a control method of the controller of the first embodiment.

The controller 100 sets an n-th (n≧2) voltage value Vn as the gate voltage Vgs applied to the gate terminal G of the switching element SW (step S1). Step S1 corresponds to the first processing. The n-th voltage value Vₙ is, for example, a value that ΔVgs is subtracted from the (n−1)-th voltage value Vₙ₋₁ used just before. ΔVgs may be pre-determined as a fixed value. In this example, both of the n-th voltage value Vₙ and the (n−1)-th voltage value Vₙ₋₁ are negative voltage values. In this example, the n-th voltage value Vₙ is a value lower than the (n−1)-th voltage value Vₙ₋₁.

The controller 100 performs the switching operation on the basis of the n-th voltage value Vₙ, and determines whether the drain current Id flowing through the drain terminal D of the switching element SW increases or not (step S2). Step S2 corresponds to the second processing. The controller 100 compares an (n−1)-th current value Iₙ₋₁ of the drain current Id after changing the gate voltage Vgs from the (n−1)-the voltage value Vₙ₋₁ to zero with an n-th current value Iₙ of the drain current Id after changing the gate voltage Vgs from the n-th voltage value Vₙ to zero. The last minute (n−1)-th current value Iₙ₋₁ may be stored in a memory included in the controller 100. The controller determines whether the n-th current value Iₙ is larger than the (n−1)-th current value Iₙ₋₁ or not.

Here, the switching element SW is the normally-on element. For this reason, in a state where the (n−1)-th voltage value Vₙ₋₁ or the n-th voltage value Vₙ is not applied as the gate voltage Vgs, the switching element SW is in turning off, and the drain current Id does not flow. On the other hand, in a state where the gate voltage Vgs is not applied, resulting in turning on, and the drain current Id flows.

In step S2, another processing may be performed. That is, the controller compares the (n−1)-th current value Iₙ₋₁ of the drain current Id after changing the gate voltage Vgs from the (n−1)-the voltage value Vₙ₋₁ to zero with the n-th current value Iₙ of the drain current Id after changing the gate voltage Vgs from the n-th voltage value Vₙ to zero. When the n-th current value Iₙ is larger than the (n−1)-th current value Iₙ₋₁, the controller 100 determines whether a difference between the n-th current value Iₙ and the (n−1)-th current value Iₙ₋₁ is larger than a threshold value or not.

In the case where the controller 100 judges that the drain current Id is not increased (case of N=0) in step S2, the controller increments n by 1 (step S3) and returns to step S1 and repeats the processing.

In the case where the controller 100 judges that the drain current Id increases (case of YES) in step S2, the controller sets the (n−1)-th voltage value Vₙ₋₁ used just before as the gate voltage Vgs (step S4). Step S4 corresponds to the third processing. That is, the gate voltage vgs is controlled to the (n−1)-th voltage value Vₙ₋₁ used just before. The (n−1)-th voltage value Vₙ₋₁ is a voltage value of the gate voltage Vgs at the lowest on-resistance.

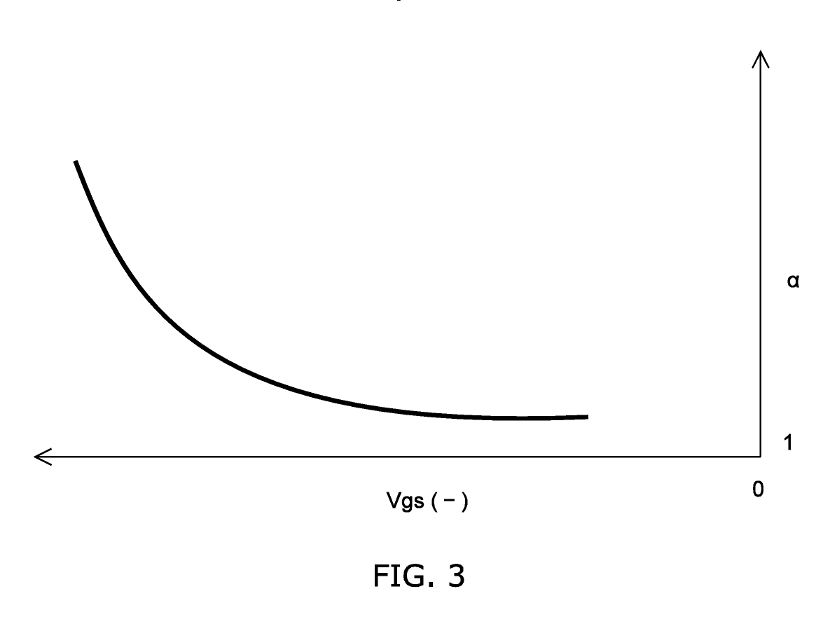

FIG. 3 is a graph illustrating an on-resistance characteristic of a normally-on switching element.

FIG. 3 shows the relationship between the gate voltage and the on-resistance increasing rate of the normally-on switching element SW.

In the drawing, α in a vertical axis shows a ratio of the on-resistance to the on-resistance initial value (on-resistance increasing rate), and Vgs in the horizontal axis shows the gate voltage (V) applied to the gate terminal. The gate voltage Vgs is a negative voltage.

As shown in FIG. 3, it is seen that in the normally-on switching element SW, the on-resistance increasing rate a increases with gate voltage Vgs decrease. That is, too much low gate voltage Vgs increases the on-resistance of the switching element SW and the power loss, and thus is not favorable.

The controller 100 according to the embodiment performs the first processing for changing the gate voltage Vgs applied to the terminal G of the switching element SW from the first voltage value V1 to the second voltage value V2, the second processing determining whether the drain current Id flowing through the drain terminal D of the switching element SW increases or not, and the third processing controlling the gate voltage Vgs to the first voltage value V1 when the drain current Id is judged to increase. That is, while changing the voltage value of the gate voltage Vgs, the increase of the drain current Id is detected. Thereby, the voltage value of the gate voltage Vgs at the lowest on-resistance is detected, and the detected voltage value is set as the gate voltage Vgs of the switching element SW.

According to the embodiment, the on-resistance of the switching element can be small and the power loss can be suppressed. This allows the controller which is able to efficiently control the switching element to be provided.

The embodiment is not limited to the controller. For example, it may be the mode of a control method of the controller, furthermore may be the mode of a program for executing the control method.

### Second Embodiment

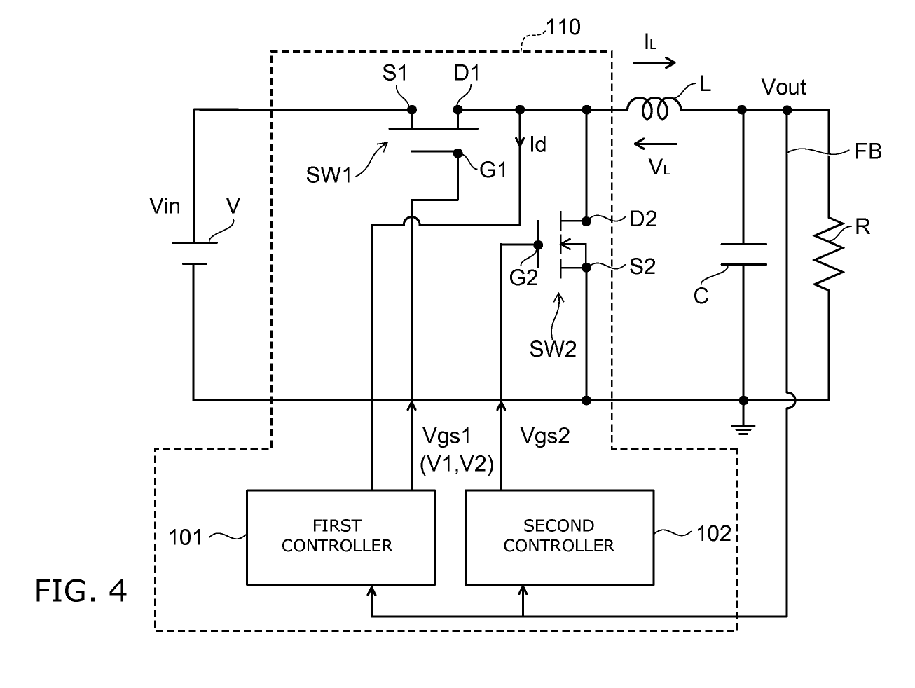

FIG. 4 is a circuit diagram illustrating a converter of a second embodiment.

FIG. 4 illustrates a converter incorporating the controller of FIG. 1.

The converter 110 according to the embodiment is, for example, a synchronous rectification type step-down converter.

As shown in FIG. 4, a DC power source V and a load circuit R are connected to the converter 110. The DC power source V generates an input voltage Vin and supplies the generated input voltage Vin to the converter 110. The converter 110 decreases the input voltage Vin to generate an output voltage Vout with a desired potential, and supplies the generated output voltage Vout to the load circuit R.

The converter 110 includes a first switching element SW1, a second switching element SW2, a first controller 101, and a second controller 102. The converter 110 is connected to an inductor L, a capacitor C, and a feedback circuit FB.

The first switching element SW1 is a normally-on transistor element. The first switching element SW1 includes a first source terminal S1, a first gate terminal G1, and a first drain terminal D1. The first switching element SW1 is, for example, HEMT based on a nitride semiconductor. The nitride semiconductor, for example can include GaN. In FIG. 4, HEMT of the JFET type is shown as an example of the first switching element SW1. The first switching element SW1 may be HEMT of the MOSFET type. The first switching element SW1 may be any one of a normally-on type and a normally-off type.

The first controller 101 is connected to the first gate terminal G1. The first controller 101 includes, for example, a PWM generating circuit not shown, and applies a pulse-like gate voltage Vgs1 to the first gate terminal G1 of the first switching element SW1.

The first switching element SW1 performs on-off operation in response to the gate voltage Vgs1 applied from the first controller 101, and is PWM driven. That is, the normally-on element is turned on in a state (gate voltage Vgs1=0) where the gate voltage Vgs1 is not applied. In the on-state, a current flows between the source and the drain, and a drain current Id flows. On the other hand, the normally-on element is turned off, in a state where a prescribed negative voltage is applied as the gate voltage Vgs1. In the off-state, a current does not flow between the source and the drain, and the drain current Id does not flow.

The controller 101 according to the embodiment performs the first processing for changing the gate voltage Vgs1 applied to the terminal G1 from the first voltage value V1 to the second voltage value V2, the second processing determining whether the drain current Id flowing through the drain terminal D1 increases or not, and the third processing controlling the gate voltage Vgs1 to the first voltage value V1 when the drain current Id is judged to increase. That is, the controller 101 performs the similar processing to the controller 100 described in the first embodiment (FIG. 1).

The second switching element SW2 is, for example, a normally-off transistor element. The second switching element SW2 includes a second source terminal S2, a second gate terminal G2, and a second drain terminal D2. The second switching element SW2 can include, for example, MOSFET (Metal Oxide Semiconductor Field Effect Transistor).

The first controller 102 is connected to the second gate terminal G1. The second controller 102 includes, for example, a PWM generating circuit not shown, and applies a pulse-like gate voltage Vgs2 to the second gate terminal G2 of the second switching element SW2. In this example, the first controller 101 and the second controller 102 are formed separately. The first controller 101 and the second controller 102 may be formed collectively.

The second switching element SW2 performs on-off operation in response to the gate voltage Vgs2 applied from the second controller 102, and is PWM driven. That is, the normally-off element is turned off in a state where a prescribed positive voltage is applied as the gate voltage Vgs2. On the other hand, the normally-off element is turned off in a state where the gate voltage Vgs2 is not applied (case of Vgs2=0).

One end of the inductor L is connected to the first drain terminal D1, and one other end is connected to the load circuit R. One of the capacitor is connected between the inductor L and the load circuit R, one other end is connected to ground. The second drain terminal of the second switching element SW2 is connected between the first drain terminal D1 and the inductor L, and the second source terminal S2 is connected to ground. The feedback circuit FB feeds back the output voltage Vout to the load circuit R into the first controller 101 and the second controller 102. The first source terminal S1 is connected to the DC power source.

The operation example of the converter 110 according to the embodiment will be described.

The first controller 101 sets the gate voltage Vgs1 supplied to the first gate terminal G1 of the first switching element SW1 to 0 (zero). Thereby, the first switching element SW1 enters the on-state. At this time, the second switching element SW2 enters the off-state (gate voltage Vgs2=0). When the first switching element SW1 is turned on, the input voltage Vin is applied to the inductor L. In the inductor L, electric energy is converted to magnetic energy to be stored. This charges the inductor L. A current I_{L} flowing through the inductor L increases with time. The current I_{L} flowing through the inductor L is a direct current including a direct current component and a ripple component. The capacitor C removes the ripple component of this current I_{L} to smooth the current I_{L}. A voltage V_{L} occurs in the inductor L in order to cancel the input voltage Vin. For this reason, the input voltage Vin is stepped-down by the voltage V_{L}. Thereby, the output voltage Vout becomes lower than the input voltage Vin. The capacitor C is charged by the output voltage Vout and both end voltage of the capacitor C is the output voltage Vout.

The first controller 101 supplies a prescribed negative voltage as the gate voltage Vgs1 to the first gate terminal G1 of the first switching element SW1. Thereby, the first switching element SW1 enters the off-state. At this time, a prescribed positive voltage is supplied to the second switching element SW2 as the gate voltage Vgs2, and the on-state occurs. When the first switching element SW1 is turned off, the magnetic energy stored in the inductor L via the second switching element SW2 is discharged as the electric energy. That is, since the inductor L and the capacitor C are connected in parallel, the both end voltage of the inductor L is also the output voltage Vout. The inductor L converts the magnetic energy to the electric energy at the output voltage Vout and the current I_{L} occurs.

In the converter 110, the feedback control is performed by the first controller 101, the second controller 102 and the feedback circuit FB. The feedback control controls the output voltage Vout to be constantly the reference value (constant). For example, the on-resistance increases in the first switching element SW1, the power loss increases and the output voltage Vout decreases. In order to recover the decreased output voltage Vout to the reference value, the drain current ID is increased. Thereby, the output voltage Vout is kept at the reference value.

That is, the increase of the drain current Id means the increase of the on-resistance (increase of power loss). For this reason, it becomes possible to detect the increase of the on-resistance by detecting the increase of the drain current Id. The controller 101 sets the first voltage value V1 as the gate voltage Vgs1, performs the switching operation on the basis of the first voltage value V1, and store the value of the drain current Id. In this example, the first voltage value V1 is an initial value. The second voltage value V2 is set as the gate voltage Vgs1. The first switching element SW1 is a normally-on type, and thus both of the first voltage value V1 and the second voltage value V2 are negative voltage values. For example, the absolute value of the second voltage value V2 is larger than the absolute value of the first voltage value V1. That is, the second voltage value V2 is a value lower than the first voltage value V1. The controller 101 performs the switching operation on the basis of the second voltage value V2, and determines whether the drain current Id increases or not. When the drain current ID is judged to increase, the first voltage value V1 used just before the second voltage value V2 is set as the gate voltage Vgs1. When the drain current Id is judged not to increase, a negative voltage value further lower than the second voltage value V2 is set as the gate voltage Vgs1 and the similar processing is repeated.

In this example, the first voltage value V1 is a voltage value of the gate voltage Vgs1 at the lowest on-resistance. In the embodiment, while changing the voltage value of the gate voltage Vgs1, the increase of the drain current Id is detected. Specifically, the control method described in FIG. 2 is performed. Thereby, the voltage value of the gate voltage Vgs1 at the lowest on-resistance is detected, and the detected voltage value is set as the gate voltage Vgs1 of the first switching element SW1.

The set of the gate voltage Vgs1 may be made regularly at a prescribed timing, alternately may be made irregularly at an arbitrary timing. Thereby, the on-resistance of the first switching element SW1 can be small and the power loss can be suppressed. Thereby, the first switching element SW1 can be controlled efficiently.

In this example, the first switching element SW1 is set to the normally-on type, and the second switching element SW2 is set to the normally-off type. The first switching element SW1 may be set to the normally-off type, and the second switching element SW2 may be set to the normally-on type. Both of the first switching element SW1 and the second switching element SW2 may be set to the normally-on type. The control method of the embodiment could be similarly applied to the normally-on element.

In this way, according to the embodiment, the on-resistance of the switching element can be small and the power loss can be suppressed. This allows the converter which is able to efficiently control the switching element to be provided.

### Third Embodiment

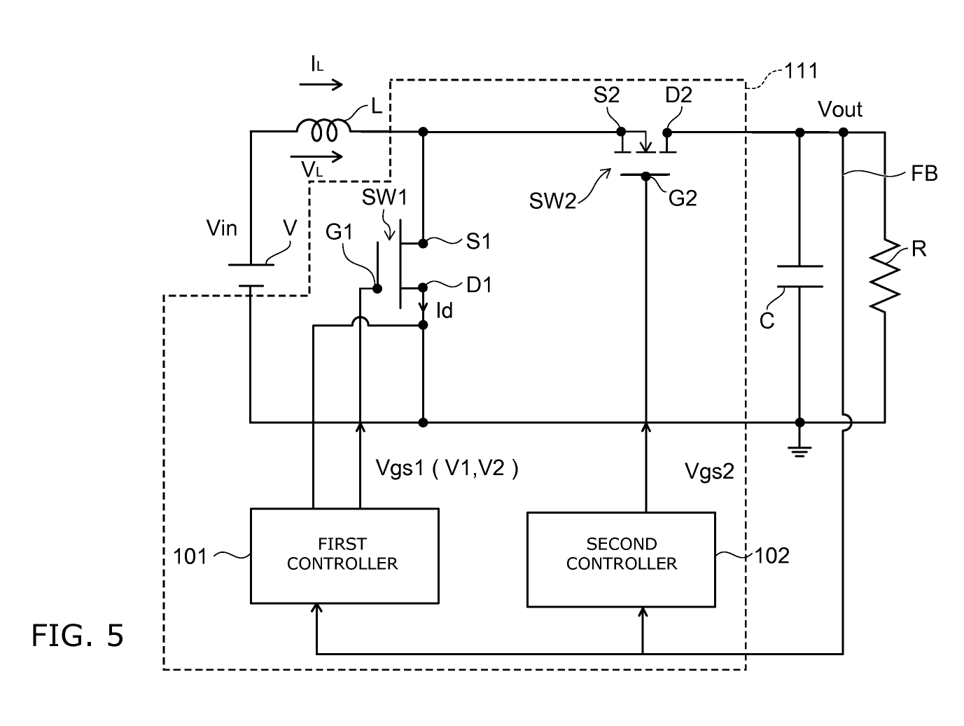

FIG. 5 is a circuit diagram illustrating a converter of a third embodiment.

FIG. 5 illustrates another converter incorporating the controller of FIG. 1.

The converter 111 according to the embodiment is, for example, a synchronous rectification type step-up converter.

As shown in FIG. 5, the DC power source V and the load circuit R are connected to the converter 111. The DC power source V generates the input voltage Vin and supplies the generated input voltage Vin to the converter 111. The converter 110 increases the absolute value of the input voltage Vin to generate the output voltage Vout with a desired potential, and supplies the generated output voltage Vout to the load circuit R.

The converter 111 includes the first switching element SW1, the second switching element SW2, the first controller 101, and the second controller 102. The converter 111 is connected to the inductor L, the capacitor C, and the feedback circuit FB.

The first switching element SW1 is the normally-on transistor element. The first switching element SW1 includes the first source terminal S1, the first gate terminal G1, and the first drain terminal D1. The first switching element SW1 is, for example, HEMT based on a nitride semiconductor. The nitride semiconductor, for example can include GaN. In FIG. 5, HEMT of the JFET type is shown as an example of the first switching element SW1. The first switching element SW1 may be HEMT of the MOSFET type. The first switching element SW1 may be any one of a normally-on type and a normally-off type.

The first controller 101 is connected to the first gate terminal G1. The first controller 101 includes, for example, a PWM generating circuit not shown, and applies a pulse-like gate voltage Vgs1 to the first gate terminal G1 of the first switching element SW1.

The first switching element SW1 performs on-off operation in response to the gate voltage Vgs1 applied from the first controller 101, and is PWM driven. That is, the normally-on element is turned on in a state (gate voltage Vgs1=0) where the gate voltage Vgs1 is not applied. In the on-state, a current flows between the source and the drain, and a drain current Id flows. On the other hand, the normally-on element is turned off, in a state where a prescribed negative voltage is applied as the gate voltage Vgs1. In the off-state, a current does not flow between the source and the drain, and the drain current Id does not flow.

The controller 101 according to the embodiment performs the first processing for changing the gate voltage Vgs1 applied to the terminal G1 from the first voltage value V1 to the second voltage value V2, the second processing determining whether the drain current Id flowing through the drain terminal D1 increases or not, and the third processing controlling the gate voltage Vgs1 to the first voltage value V1 when the drain current Id is judged to increase. That is, the controller 101 performs the similar processing to the controller 100 described in the first embodiment (FIG. 1).

The second switching element SW2 is, for example, a normally-off transistor element. The second switching element SW2 includes a second source terminal S2, a second gate terminal G2, and a second drain terminal D2. The second switching element SW2 can include, for example, MOSFET.

The first controller 102 is connected to the second gate terminal G1. The second controller 102 includes, for example, a PWM generating circuit not shown, and applies a pulse-like gate voltage Vgs2 to the second gate terminal G2 of the second switching element SW2. In this example, the first controller 101 and the second controller 102 are formed separately. The first controller 101 and the second controller 102 may be formed collectively.

The second switching element SW2 performs on-off operation in response to the gate voltage Vgs2 applied from the second controller 102, and is PWM driven. That is, the normally-off element is turned off in a state where a prescribed positive voltage is applied as the gate voltage Vgs2. On the other hand, the normally-off element is turned off in a state where the gate voltage Vgs2 is not applied (case of Vgs2=0).

One end of the inductor L is connected to the DC power source V, and one other end is connected to the load circuit R. The second source terminal S2 and the second drain terminal D2 of the second switching element SW2 are connected between the inductor L and the load circuit R. The second controller 102 is connected to the second gate terminal G2. One end of the capacitor C is connected between the second drain terminal D2 and the load circuit R, and one other end is connected to ground. The feedback circuit FB feeds back the output voltage Vout to the load circuit R into the first controller 101 and the second controller 102. The source terminal S1 is connected between the inductor L and the second source terminal S2. The first drain terminal D1 is connected to ground.

The operation example of the converter 111 according to the embodiment will be described.

The first controller 101 supplies the prescribed negative voltage to the first gate terminal G1 of the first switching element SW1 as the gate voltage Vgs1. Thereby, the first switching element SW1 enters the off-state. At this time, the prescribed positive voltage is supplied to the second switching element SW2 as the gate voltage Vgs2, and the second switching element SW2 enters the on-state. When the second switching element SW2 is turned on, the input voltage Vin is applied and a current flows through the inductor L and the load circuit R. Thereby, charge to the inductor L starts.

The first controller 101 sets the gate voltage Vgs1 supplied to the first gate terminal G1 of the first switching element SW1 to 0 (zero). Thereby, the first switching element SW1 enters the on-state. At this time, the second switching element SW2 enters the off-state (gate voltage Vgs2=0). When the first switching element SW1 is turned on, a current flows through the inductor L via the first switching element SW1. Because the first switching element SW1 has a smaller resistance than the load circuit R, the current I_{L} flowing through the inductor L increases more than the current flowing through the load circuit R. The inductor is further charged with increase of the current. That is, in the inductor L, the electric energy is converted into the magnetic energy to be stored.

When the first switching element SW1 is re-turned off and the second switching element SW2 is re-turned on, the current flows through the inductor L and the load circuit R via the second switching element SW2. Because the load circuit R has a larger resistance than the first switching element SW1, the current I_{L} flowing through the inductor decreases. For this reason, the inductor L discharges the stored magnetic energy as the electric energy. The voltage V_{L} occurs in the similar way to the input voltage Vin. For this reason, the input voltage Vin is stepped-up by the voltage V_{L}. Thereby, the output voltage Vout is higher than the input voltage Vin. The capacitor C is charged to have the output voltage Vout.

When the first switching element SW1 is re-turned on and the second switching element SW2 is re-turned off, the current flows through the first switching element SW1, and the inductor L is charged. During charging the inductor L, the output voltage Vout charged in the capacitor C is supplied to the load circuit R.

In the converter 111, the feedback control is performed by the first controller 101, the second controller 102 and the feedback circuit FB. The feedback control controls the output voltage Vout to be constantly the reference value (constant). For example, the on-resistance increases in the first switching element SW1, the power loss increases and the output voltage Vout decreases. In order to recover the decreased output voltage Vout to the reference value, the drain current ID is increased. Thereby, the output voltage Vout is kept at the reference value.

That is, the increase of the drain current Id means the increase of the on-resistance (increase of power loss). For this reason, it becomes possible to detect the increase of the on-resistance by detecting the increase of the drain current Id. The controller 101 sets the first voltage value V1 as the gate voltage Vgs1, performs the switching operation on the basis of the first voltage value V1, and store the value of the drain current Id. In this example, the first voltage value V1 is an initial value. The second voltage value V2 is set as the gate voltage Vgs1. The first switching element SW1 is a normally-on type, and thus both of the first voltage value V1 and the second voltage value V2 are negative voltage values. For example, the absolute value of the second voltage value V2 is larger than the absolute value of the first voltage value V1. That is, the second voltage value V2 is a value lower than the first voltage value V1. The controller 101 performs the switching operation on the basis of the second voltage value V2, and determines whether the drain current Id increases or not. When the drain current ID is judged to increase, the first voltage value V1 used just before the second voltage value V2 is set as the gate voltage Vgs1. When the drain current Id is judged not to increase, a negative voltage value further lower than the second voltage value V2 is set as the gate voltage Vgs1 and the similar processing is repeated.

In this example, the first voltage value V1 is a voltage value of the gate voltage Vgs1 at the lowest on-resistance. In the embodiment, while changing the voltage value of the gate voltage Vgs1, the increase of the drain current Id is detected. Specifically, the control method described in FIG. 2 is performed. Thereby, the voltage value of the gate voltage Vgs1 at the lowest on-resistance is detected, and the detected voltage value is set as the gate voltage Vgs1 of the first switching element SW1.

The set of the gate voltage Vgs1 may be made regularly at a prescribed timing, alternately may be made irregularly at an arbitrary timing. Thereby, the on-resistance of the first switching element SW1 can be small and the power loss can be suppressed. Thereby, the first switching element SW1 can be controlled efficiently.

In this example, the first switching element SW1 is set to the normally-on type, and the second switching element SW2 is set to the normally-off type. The first switching element SW1 may be set to the normally-off type, and the second switching element SW2 may be set to the normally-on type. Both of the first switching element SW1 and the second switching element SW2 may be set to the normally-on type. The control method of the embodiment could be similarly applied to the normally-on element.

In this way, according to the embodiment, the on-resistance of the switching element can be small and the power loss can be suppressed. This allows the converter which is able to efficiently control the switching element to be provided.

The synchronous rectification type step-down converter and the synchronous rectification type step-up converter have been described as the embodiment. The embodiment may include, for example, the synchronous rectification type step-up converter and other scheme converters. The converter based on the normally-on switching element could be applied to the embodiment.

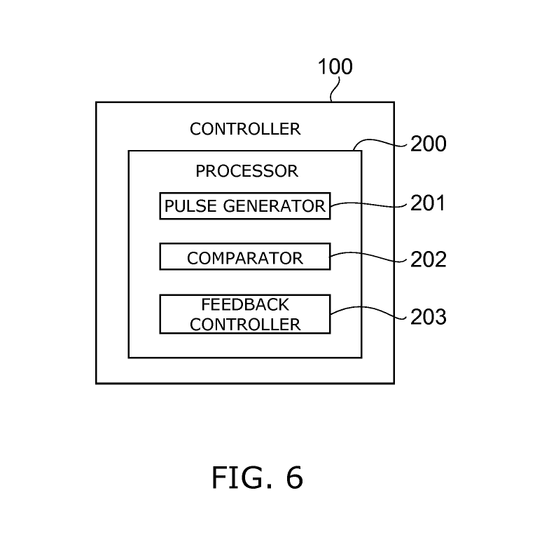

FIG. 6 is a block diagram illustrating the controller of the embodiment.

The controller shown in FIG. 1 includes a processor 200. For example, CPU can be used for the processor 200. The processor 200 can include a processing circuit such as CPU. The processor 200 includes a pulse generator 201, a comparator 202, and a feedback controller 203. The pulse generator 201 performs the first processing. The comparator 202 performs the second processing. The feedback controller 203 performs the third processing. As described previously, the first processing changes the gate voltage Vgs applied to the gate terminal G of the switching element SW from the first voltage value V1 to the second voltage value V2. The second processing determines whether the drain current flowing through the drain terminal D of the switching element SW increases or not. Third processing controls the gate voltage Vgs to the first voltage value V1 when the drain current Id is judged to increase.

### Fourth Embodiment

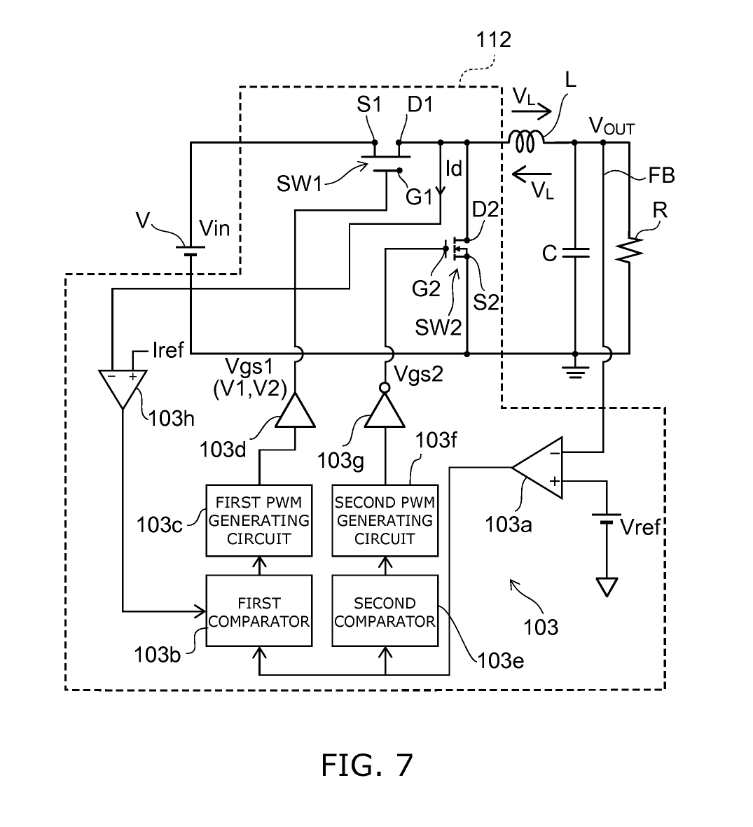

FIG. 7 is a circuit diagram illustrating a converter of a fourth embodiment.

FIG. 7 shows an example of the controller of FIG. 1 realized as an analog circuit.

The converter 112 according to the embodiment is, for example, the synchronous rectification type step-down converter.

As shown in FIG. 7, the DC power source V and the load circuit R are connected to the converter 112. The DC power source V generates the input voltage Vin and supplies the generated input voltage Vin to the converter 112. The converter 112 decreases the input voltage Vin to generate the output voltage Vout with a desired potential, and supplies the generated output voltage Vout to the load circuit R.

The converter 112 includes the first switching element SW1, the second switching element SW2, and a controller 103. The converter 112 is connected to the inductor L, the capacitor C, and the feedback circuit FB. The constituent components other than the controller 103 are much the same for the converter 110 described in the second embodiment (FIG. 4).

The controller 103 is constituted as the analog circuit. The controller 103 includes a first error amplifier 103a, a first compensator 103b, a first PWM generating circuit 103c, a first buffer amplifier 103d, a second compensator 103e, a second PWM generating circuit 103f, a second buffer amplifier 103g, and a second error amplifier 103h.

The first error amplifier 103a compares the output voltage Vout with the reference voltage Vref, amplifies the voltage difference, and outputs to each of the first compensator 103b and the second compensator 103e.

The first compensator 103b outputs a compensation signal for compensating the voltage difference to be zero to the first PWM generating circuit 103c. The first PWM generating circuit 103c generates a pulse-like gate voltage based on the compensation signal and outputs to the first buffer amplifier 103d. The first buffer amplifier 103d fairs a waveform of the gate voltage and applies the gate voltage Vgs1 after fairing to the first gate terminal G1.

The second compensator 103e outputs a compensation signal for compensating the voltage difference to be zero to the second PWM generating circuit 103f. The second PWM generating circuit 103f generates a pulse-like gate voltage based on the compensation signal and outputs to the second buffer amplifier 103g. The second buffer amplifier 103g fairs a waveform of the gate voltage and applies the gate voltage Vgs2 after the fairing to the second gate terminal G2.

In the case where the gate voltage is controlled in response to the increase of the drain current, the drain current Id of the first switching element SW1 is input to the second error amplifier 103h. At this time, the gate voltage of the second voltage value V2 which changed from the first voltage value V1 is applied to the first gate terminal G1. The second error amplifier 103h compares the drain current Id with the reference current Iref, amplifies the current difference, and outputs to the first compensator 103b.

The first compensator 103b determines whether the drain current Id at the second voltage value V2 increases more than the drain current Id at the first voltage value V1. When the drain current Id is determined to increase, the first compensator 103b directs the first PWM generating circuit 103c to return the gate voltage to the first voltage value V1. The first PWM generating circuit 103c generates the pulse-like gate voltage in response to the first voltage value based on the direction from the first compensator 103b and outputs the first buffer amplifier 103d. The first buffer amplifier 103d fairs the waveform of the gate voltage and applies the gate voltage Vgs1 (first voltage value V1) after the fairing to the first gate terminal G1.

The first compensator 103b and the second compensator 103e may be constituted collectively. The first PWM generating circuit 103c and the second PWM generating circuit 103f may be constituted as one PWM generating circuit.

### Fifth Embodiment

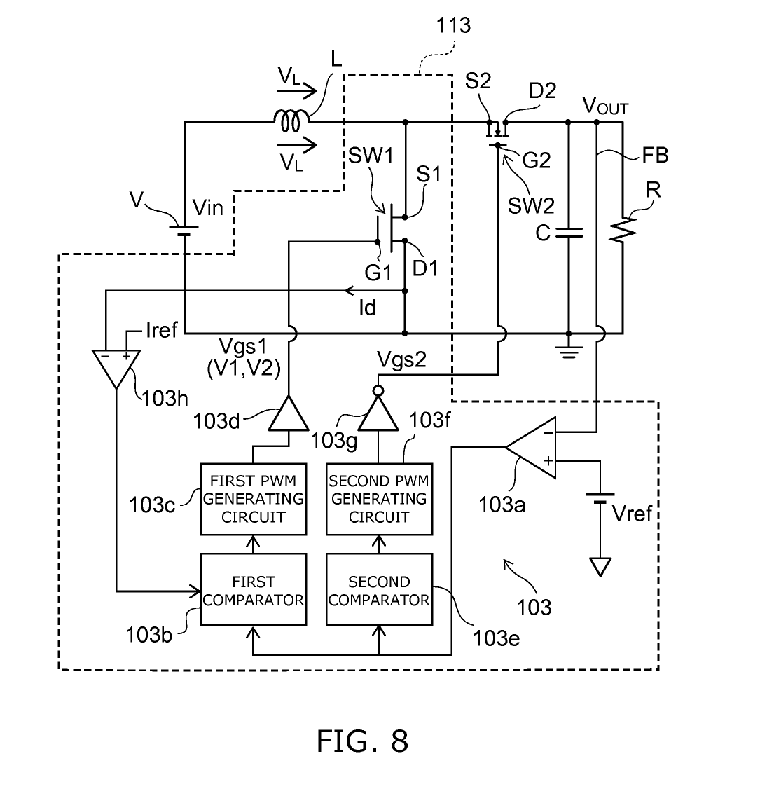

FIG. 8 is a circuit diagram illustrating a converter of a fifth embodiment.

FIG. 8 shows an example of the controller of FIG. 1 realized as an analog circuit.

The converter 113 according to the embodiment is, for example, the synchronous rectification type step-up converter.

As shown in FIG. 8, the DC power source V and the load circuit R are connected to the converter 113. The DC power source V generates the input voltage Vin and supplies the generated input voltage Vin to the converter 113. The converter 113 increases the absolute value of the input voltage Vin to generate the output voltage Vout with a desired potential, and supplies the generated output voltage Vout to the load circuit R.

The converter 113 includes the first switching element SW1, the second switching element SW2, and a controller 103. The converter 113 is connected to the inductor L, the capacitor C, and the feedback circuit FB. The constituent components other than the controller 103 are much the same for the converter 111 described in the second embodiment (FIG. 5). The constitution and the operation of the controller 103 are as described in the fourth embodiment (FIG. 7). The repeated description will be omitted here.

In this way, according to the embodiment, the controller can also be realized from the analog circuit. According to the embodiment, the converter incorporating the controller realized from the analogue circuit can be provided.

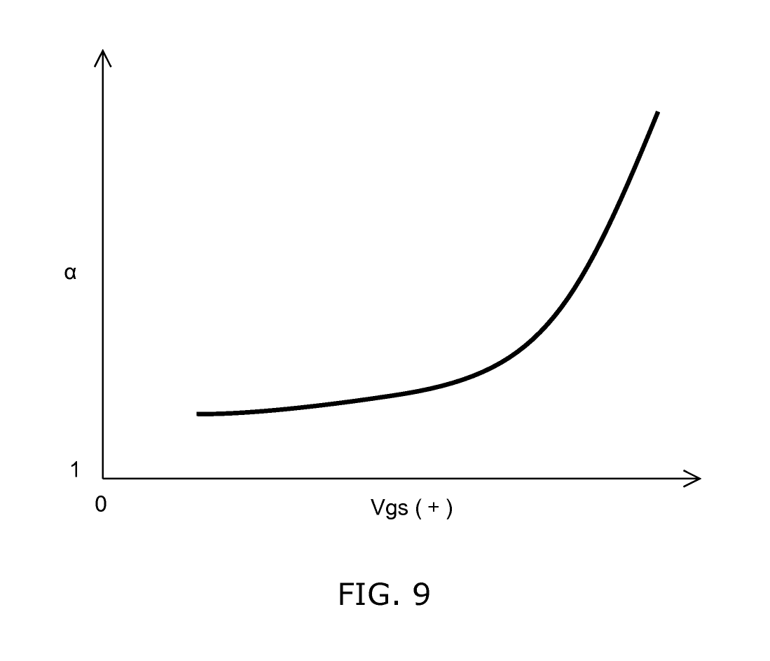

FIG. 9 is a graph illustrating an on-resistance characteristic of a normally-off switching element.

FIG. 9 shows the relationship between the gate voltage and the on-resistance increasing rate of the normally-off switching element SW.

In the drawing, a in a vertical axis shows a ratio of the on-resistance to the on-resistance initial value (on-resistance increasing rate), and Vgs in the horizontal axis shows the gate voltage (V) applied to the gate terminal. The gate voltage Vgs is a positive voltage.

As shown in FIG. 9, it is recognized that in the normally-off switching element SW, the on-resistance increasing rate a increases with gate voltage Vgs increase. That is, making the gate voltage Vgs excessively high is not favorable because the on-resistance of the switching element SW increases and the power loss increases.

In this example, both of the first voltage value V1 and the second voltage value V2 are positive voltage values because the switching element SW is a normally-off type. For example, the absolute value of the second voltage value V2 is larger than the absolute value of the first voltage value V1. That is, the second voltage value V2 is a value higher than the first voltage value V1.

That is, the embodiments recited above are not limited to the normally-on type. The embodiments can be applied to the normally-off switching element.

According to the embodiment, the controller, the converter, and the control method which are able to efficiently control the switching element can be provided.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as switching elements and controllers etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all controllers, converters, and control methods practicable by an appropriate design modification by one skilled in the art based on the controllers, the converters, and the control methods described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A controller being able to control a switching element, comprising: a processor,
the processor changing a gate voltage applied to a gate terminal of the switching element from a first voltage value to a second voltage value, and controlling the gate voltage to the first voltage value when a drain current flowing through a drain terminal of the switching element increases.

2. The controller according to claim 1, wherein
the processor compares a first current value of the drain current after changing the gate voltage from the first voltage value to zero with a second current value of the drain current after changing the gate voltage from the second voltage value to zero, and determines whether the second current value is larger than the first current value or not.

3. The controller according to claim 1, wherein
the processor compares a first current value of the drain current after changing the gate voltage from the first voltage value to zero with a second current value of the drain current after changing the gate voltage from the second voltage value to zero, and determines whether a difference between the second current value and the first current value is larger than a threshold or not when the second current value is larger than the first current value.

4. The controller according to claim 1, wherein
the first voltage value and the first voltage value are a negative voltage value, and
an absolute value of the second voltage value is larger than an absolute value of the first voltage value.

5. The controller according to claim 1, wherein
the first voltage value and the first voltage value are a positive voltage value, and
an absolute value of the second voltage value is larger than an absolute value of the first voltage value.

6. A converter comprising:
a first switching element including a first source terminal, a first gate terminal, and a first drain terminal; and
a first controller including a processor which controls the first switching element,
the processor changing a gate voltage applied to the first gate terminal from a first voltage value to a second voltage value, and controlling the gate voltage to the first voltage value when a drain current flowing through the first drain terminal increases.

7. The converter according to claim 6, wherein
the first switching element is a transistor based on a nitride semiconductor.

8. The converter according to claim 6, further comprising:
a second switching element; and
a second controller,
an inductor, a capacitor, and a feedback circuit being connected,
one end of the inductor being connected to the first drain terminal, and one other end of the inductor being connected to a load circuit,
one end of the capacitor being connected between the inductor and the load circuit, and one other end being connected to ground,
the second switching element including a second source terminal, a second gate terminal, and a second drain terminal, and the second drain terminal being connected between the first drain terminal and the inductor, and the second source terminal being connected to ground,
the second controller being connected to the second gate terminal,
the feedback circuit feeding back an output voltage to the load circuit to the first controller and the second controller, and
the first source terminal being connected to a DC power source.

9. The converter according to claim 6, further comprising:
a second switching element; and
a second controller,
an inductor, a capacitor, and a feedback circuit being connected,
one end of the inductor being connected to a DC power source, and one other end of the inductor being connected to a load circuit,
the second switching element including a second source terminal, a second gate terminal, and a second drain terminal, and the second source terminal and the second drain terminal being connected between the inductor and the load circuit, the second controller being connected to the second gate terminal,
one end of the capacitor being connected between the second drain terminal and the load circuit, and one other end being connected to ground,
the feedback circuit feeding back an output voltage to the load circuit to the first controller and the second controller,
the first source terminal being connected between the inductor and the second source terminal, and
the first drain terminal being connected to ground.

10. The converter according to claim 8, wherein
the second switching element is a normally-off type.

11. The converter according to claim 8, wherein
the second switching element is a normally-on type.

12. A control method for controlling a switching element, the method comprising:
performing a processing for changing a gate voltage applied to a gate terminal of the switching element from a first voltage value to a second voltage value; and
performing a processing for controlling the gate voltage to the first voltage value when a drain current flowing through a drain terminal of the switching element increases.

13. The method according to claim 12, further comprising:
performing a processing for comparing a first current value of the drain current after changing the gate voltage from the first voltage value to zero with a second current value after changing the gate voltage from the second voltage value to zero, and determining whether the second current value is larger than the first current value or not.

14. The method according to claim 12, further comprising:
performing a processing for comparing a first current value of the drain current after changing the gate voltage from the first voltage value to zero with a second current value after changing the gate voltage from the second voltage value to zero, and determining whether a difference between the second current value and the first current value is larger than or not when the second current value is larger than the first current value.

15. The method according to claim 12, wherein
the first voltage value and the second voltage value are a negative voltage value, and
an absolute value of the second voltage value is larger than an absolute value of the first voltage value.

16. The method according to claim 12, wherein
the first voltage value and the second voltage value are a positive voltage value, and
an absolute value of the second voltage value is larger than an absolute value of the first voltage value.
